(19) United States
(12) Patent Application Publication
(10) Pub. No.: US 2024/0096704 A1
(43) Pub. Date: Mar. 21, 2024

(54) PROCESSING METHOD OF WAFER

(71) Applicant: DISCO CORPORATION, Tokyo (JP)

(72) Inventor: Masaru NAKAMURA, Tokyo (JP)

(21) Appl. No.: 18/457,528

(22) Filed: Aug. 29, 2023

(30) Foreign Application Priority Data
Sep. 21, 2022 (JP) 2022-150230

(51) Int. Cl. H01L 21/78; H01L 21/683

(52) U.S. Cl. CPC H01L 21/78; H01L 21/6836

(57) ABSTRACT

A processing method of a wafer includes a water-soluble resin application step of applying a water-soluble resin to a front surface of the wafer, a modified-layer forming step of applying a laser beam of a wavelength that has transmissivity for the wafer, from a back surface of the wafer with a focal point of the laser beam positioned corresponding to each of dividing lines inside the wafer, thereby forming modified layers along the each of the dividing lines, a resin removing step of removing the wafer-soluble resin from the front surface of the wafer, and a dividing step of applying an external force to the wafer, thereby dividing the wafer into individual device chips.

### BACKGROUND OF THE INVENTION

### Field of the Invention

The present invention relates to a processing method of a wafer with a plurality of devices formed on a front surface thereof and defined by a plurality of intersecting dividing lines.

### Description of the Related Art

A wafer with a plurality of devices such as integrated circuits (ICs) or large-scale integration (LSI) circuits formed on a front surface thereof and defined by a plurality of intersecting dividing lines is formed to a desired thickness by a grinding machine, and is then divided into individual device chips by a dicing machine or a laser processing machine, and the divided device chips are used in electronic equipment such as mobile phones or personal computers.

The laser processing machine is configured including a chuck table that holds the wafer, a laser beam irradiation unit that applies a laser beam of a wavelength which has transmissivity for the wafer, to the wafer held on the chuck table, with a focal point of the laser beam positioned corresponding to each of the dividing lines inside the wafer, to form modified layers, and a feed mechanism that causes a relative processing feed of the chuck table and the laser beam irradiation unit, and can divide the wafer into the individual device chips with high precision (see Japanese Patent No. 3408805, for example).

As function layers that make up the devices are stacked on the front surface of the wafer, the laser beam that is to form the modified layers inside the wafer is applied from a back surface of the wafer. Further, a protective tape is arranged on the front surface of the wafer such that the devices are protected from scratches and the like when the wafer is held at the front surface thereof on the chuck table and, in addition, such that heat that occurs by the irradiation of the laser beam is allowed to dissipate to avoid deteriorations in electrical characteristics of the devices.

### SUMMARY OF THE INVENTION

If the modified layers are formed by applying, with the protective tape bonded on the front surface of the wafer, the laser beam from the back surface of the wafer with the focal point of the laser beam positioned inside the wafer, however, a problem arises in that leak light of the laser beam is applied to a self-adhesive layer of the protective tape to cause a modification of a self-adhesive material, the self-adhesive material thus modified sticks to the front surface of the wafer and is not readily removable, and the device chips are hence lowered in quality.

The present invention therefore has as an object thereof the provision of a wafer processing method which protects devices from scratches and the like when the wafer is held at a front surface thereof on a chuck table, allows heat that occurs by irradiation of a laser beam to effectively dissipate to avoid deteriorations in the electrical characteristics of device chips, and does not raise the problem that the leak light of the laser beam is applied to the self-adhesive layer of the protective tape to cause the modification of the self-adhesive material, the self-adhesive material thus modified sticks to the front surface of the wafer, and the device chips are hence lowered in quality.

In accordance with an aspect of the present invention, there is provided a processing method of a wafer with a plurality of devices formed on a front surface thereof and defined by a plurality of intersecting dividing lines. The processing method includes a protective tape arrangement step of arranging a protective tape on the front surface of the wafer, a holding step of holding, on a chuck table, the wafer on a side of the protective tape, a grinding step of grinding the wafer at a back surface thereof to thin the wafer, a protective tape separation step of separating the protective tape from the front surface of the wafer, a water-soluble resin application step of applying a water-soluble resin to the front surface of the wafer, a modified-layer forming step of applying a laser beam of a wavelength that has transmissivity for the wafer, from the back surface of the wafer with a focal point of the laser beam positioned corresponding to each of the dividing lines inside the wafer, thereby forming modified layers along the each of the dividing lines, a frame supporting step of bonding a dicing tape to a back surface of an annular frame that centrally has an opening of an inner diameter greater than a diameter of the wafer, such that the dicing tape closes the opening, and then disposing the wafer in the opening with the back surface of the wafer directed downwards, to bond the back surface of the wafer to the dicing tape, thereby supporting the wafer on the annular frame via the dicing tape, a resin removing step of removing the wafer-soluble resin from the front surface of the wafer, a dividing step of applying an external force to the wafer, thereby dividing the wafer into individual device chips, and a pickup step of picking up the device chips from the dicing tape.

Preferably, the water-soluble resin application step may be performed before the protective tape arrangement step, and the water-soluble resin may be exposed in the protective tape separation step. Preferably, the frame supporting step may be performed before the modified-layer forming step, and the laser beam may be applied from a side of the dicing tape in the modified-layer forming step.

According to the present invention, the devices on the front surface of the wafer can be protected by the water-soluble resin, and further, the heat that occurs by irradiation of the laser beam is allowed to effectively dissipate, so that a problem that the devices are deteriorated in electrical characteristics is solved. Moreover, even if the leak light of the laser beam applied from the side of the back surface of the wafer reaches the side of the front surface of the wafer, the front surface of the wafer is covered with the water-soluble resin without any self-adhesive layer, thereby solving the problem that a self-adhesive material in such a self-adhesive layer is modified by the leak light and the self-adhesive material thus modified sticks to the front surface of the wafer to deteriorate the quality of the device chips.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating a protective tape arrangement step in a wafer processing method according to an embodiment of the present invention;

FIG. 2A is a perspective view illustrating an example of a holding step in the processing method;

FIG. 2B is a perspective view illustrating an example of a grinding step in the processing method;

FIG. 3 is a perspective view illustrating an example of a protective tape separation step in the processing method;

FIG. 4 is a perspective view illustrating an example of a water-soluble resin application step in the processing method;

FIG. 5A is a perspective view illustrating an example of a modified-layer forming step in the processing method;

FIG. 5B is an enlarged fragmentary cross-sectional view illustrating a wafer in the modified-layer forming step illustrated in FIG. 5A;

FIG. 6 is a perspective view illustrating an example of a frame supporting step in the processing method;

FIG. 7 is a perspective view illustrating another example of the modified-layer forming step in the processing method;

FIG. 8 is a perspective view illustrating an example of a resin removing step in the processing method;

FIG. 9A is a concept diagram illustrating an example of a dividing step in the processing method; and

FIG. 9B is a concept diagram illustrating an example of a pickup step in the processing method.

### DETAILED DESCRIPTION OF THE PREFERRED EMBODIMENT

With reference to the attached drawings, a wafer processing method according to an embodiment of the present invention will hereinafter be described in detail.

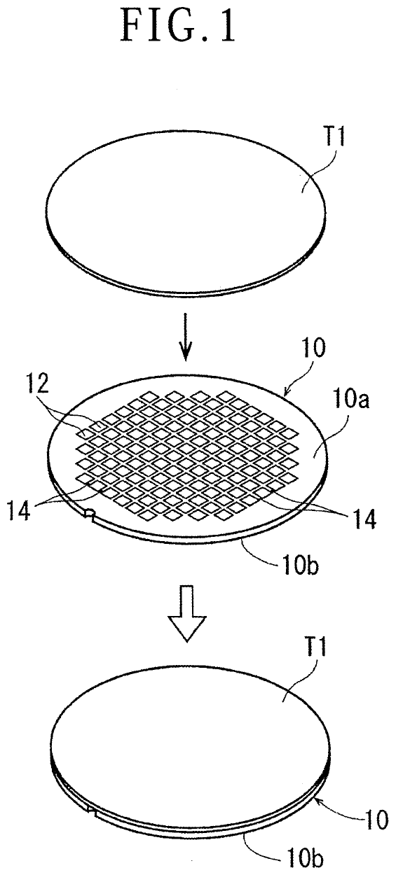

FIG. 1 illustrates a wafer 10 to be processed in the processing method of the present embodiment. The wafer 10 is, for example, a wafer of silicon, with a plurality of devices 12 formed on a front surface 10a thereof and defined by a plurality of intersecting dividing lines 14. On the front surface 10a of the wafer 10, unillustrated function layers that make up the devices 12 are stacked.

After the above-described wafer 10 has been provided, a protective tape T1 having a self-adhesive layer is arranged on and integrated with the front surface 10a of the wafer 10 (protective tape arrangement step) as illustrated in FIG. 1.

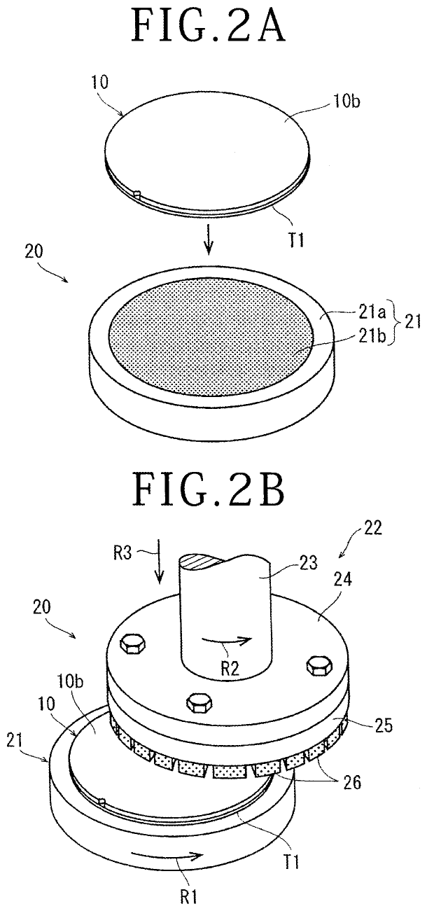

The wafer 10 is next transferred, along with the protective tape T1 integrated therewith, to a grinding machine 20, only a part of which is illustrated in FIGS. 2A and 2B. FIG. 2A illustrates a chuck table 21 that holds the wafer 10 in the grinding machine 20. The chuck table 21 includes a holding surface 21b and a frame body 21a that surrounds the holding surface 21b, and the holding surface 21b is configured with a member having air permeability. The holding surface 21b is in communication with unillustrated suction means via the frame body 21a, so that a negative pressure can be produced at the holding surface 21b.

The wafer 10 that has been transferred to the grinding machine 20 is placed on the chuck table 21 with a side of the protective tape T1 directed downwards and a back surface 10b thereof directed upwards, and the above-described suction means is then activated to hold the wafer 10 by suction on the chuck table 21 (holding step).

An unillustrated feed mechanism is next activated to position the chuck table 21 below a grinding unit 22 as illustrated in FIG. 2B. The grinding unit 22 includes a rotary spindle 23 to be rotated by an unillustrated rotary drive mechanism, a wheel mount 24 secured to a lower end of the rotary spindle 23, and a grinding wheel 25 attached to a lower surface of the wheel mount 24, and a plurality of grinding stones 26 are arranged in an annular pattern on a lower surface of the grinding wheel 25.

After the back surface 10b of the wafer 10 held on the chuck table 21 has been positioned below the grinding unit 22, the chuck table 21 is rotated in a direction indicated by an arrow R1, for example, at 300 rpm, and at the same time, the rotary spindle 23 is rotated in a direction indicated by an arrow R2, for example, at 6,000 rpm. While feeding grinding water onto the back surface 10b of the wafer 10 by an unillustrated grinding water supply unit, the grinding unit 22 is then lowered in a direction indicated by an arrow R3, to bring the grinding stones 26 into contact with the back surface 10b of the wafer 10, and the grinding wheel 25 is fed for grinding at a grinding feed rate of, for example, 1 μm/sec. Here, it is possible to proceed with the grinding while measuring the thickness of the wafer 10 by an unillustrated contact measurement gauge. After the wafer 10 has been ground to a predetermined extent at the back surface 10b thereof and thinned to have a predetermined thickness, grinding processing that grinds the back surface 10b of the wafer 10 is completed through a rinsing and drying step and the like (grinding step).

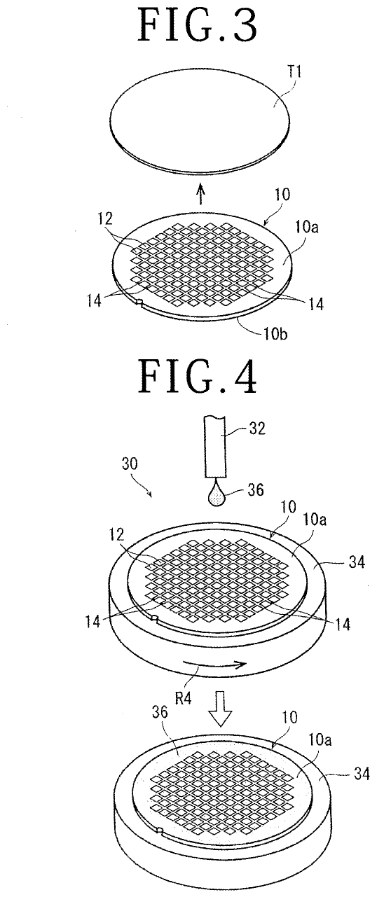

After the grinding step has been completed, the protective tape T1 is separated from the front surface 10a of the wafer 10 (protective tape separation step) as illustrated in FIG. 3.

After the protective tape separation step has been completed as described above, the wafer 10 is transferred to a water-soluble resin application machine 30, only a part of which is illustrated in FIG. 4. The water-soluble resin application machine 30 includes a water-soluble resin supply nozzle 32 and a holding table 34 configured to rotatably hold the wafer 10, and can drop a desired amount of a water-soluble resin 36, which is supplied from an unillustrated water-soluble resin supply unit onto the front surface 10a of the wafer 10 from the water-soluble resin supply nozzle 32. Examples of the water-soluble resin 36 that is dropped from the water-soluble resin supply nozzle 32 include, but are not particularly limited to, polyvinyl alcohol, polyvinyl pyrrolidone, polyethylene glycol, and the like. The wafer 10 that has been transferred to the water-soluble resin application machine 30 is placed and fixed on the holding table 34 with the front surface 10a directed upwards. The holding table 34 is then spined at high speed, so that the water-soluble resin 36 dropped from the water-soluble resin supply nozzle 32 is caused to evenly spread over the front surface 10a of the wafer 10 and is applied to the front surface 10a of the wafer 10 (water-soluble resin application step).

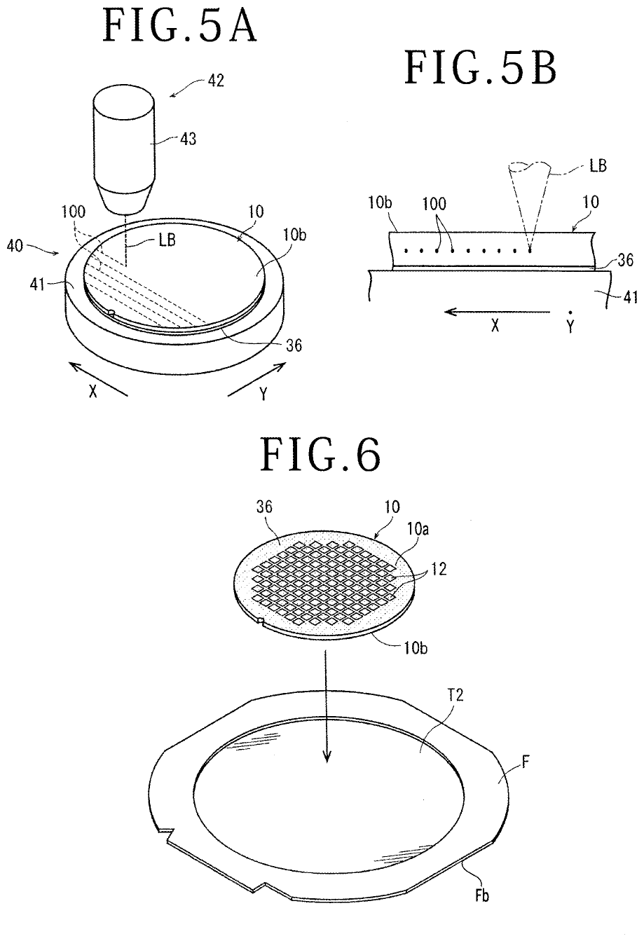

After the water-soluble resin 36 has been applied to the front surface 10a of the wafer 10 through the above-described water-soluble resin application step, the wafer 10 is transferred to a laser processing machine 40, only a part of which is illustrated in FIG. 5A. The laser processing machine 40 includes a chuck table 41 and a laser beam irradiation unit 42 that applies, to the wafer 10 held on the chuck table 41, a laser beam LB of a wavelength having transmissivity for the wafer 10. The chuck table 41 includes an unillustrated X-axis feed mechanism that causes a processing feed, in an X-axis direction, of the chuck table 41 and the laser beam irradiation unit 42, an unillustrated Y-axis feed mechanism that causes a processing feed, in a Y-axis direction, which is orthogonal to the X-axis direction, of the chuck table 41 and the laser beam irradiation unit 42, and an unillustrated rotary drive mechanism that rotates the chuck table 41.

The wafer 10 that has been transferred to the laser processing machine 40 is placed and held by suction on the chuck table 41 with the side of the front surface 10a which is covered with the water-soluble resin 36 directed downwards and the back surface 10b directed upwards. On the wafer 10 held on the chuck table 41, an alignment is performed from the side of the back surface 10b by an infrared irradiation unit and an unillustrated alignment unit including an infrared camera or the like, all of which are arranged in the laser processing machine 40, so that the positions of the dividing lines 14 formed on the front surface 10a are detected, and the wafer 10 is rotated by the rotary drive mechanism for the chuck table 41 to bring a substantially half of the dividing lines 14, which extend in a predetermined direction, into an alignment with the X-axis direction. Information on the thus-detected positions of the dividing lines is stored in an unillustrated controller.

Based on the information on the positions detected by the above-described alignment, a condenser 43 of the laser beam irradiation unit 42 is positioned above a processing start position on a predetermined one of the dividing lines 14 extending in a first direction. Then, as illustrated in FIG. 5B, the laser beam LB is applied from the back surface 10b of the wafer 10 with the focal point of the laser beam LB positioned corresponding to the predetermined dividing line 14 inside the wafer 10, and at the same time, the wafer 10 is fed for processing along with the chuck table 41 in the X-axis direction, whereby modified layers 100 are formed along the predetermined dividing line 14 which extends in the first direction, inside the wafer 10. After the modified layers 100 have been formed along the predetermined dividing line 14 inside the wafer 10, the wafer 10 is fed for indexing in the Y-axis direction by an interval of the dividing lines 14, and the unprocessed dividing line 14 which is adjacent, in the Y-axis direction, to the processed predetermined dividing line 14 is positioned right below the condenser 43. In a manner similar to that described above, the laser beam LB is then applied with the focal point of the laser beam LB positioned corresponding to the adjacent unprocessed dividing line 14 inside the wafer 10, and the wafer 10 is fed for processing in the X-axis direction to form modified layers 100. Similarly and alternately, the wafer 10 is fed for processing in the X-axis direction and for indexing in the Y-axis direction, so that modified layers 100 are formed corresponding to all the dividing lines 14 which extend in the first direction, inside the wafer 10.

The wafer 10 is next rotated 90 degrees to bring the remaining dividing lines 14 which extend in a second direction orthogonal to the dividing lines 14 along which the modified layers 100 have already been formed, into alignment with the X-axis direction. With the focal point of the laser beam LB also positioned corresponding to the remaining respective dividing lines 14 in a manner similar to that described above, the laser beam LB is applied to form modified layers 100 along all the dividing lines 14 which are formed on the front surface 10a of the wafer 10, inside the wafer 10 (modified-layer forming step).

It is to be noted that laser processing conditions under which the above-described modified-layer forming step is performed may be set, for example, as follows.
Wavelength: 1,342 nm
Average power: 1.0 W
Repetition frequency: 90 kHz
Processing feed rate: 700 mm/sec

After the modified-layer forming step has been performed as described above, the wafer 10 is unloaded from the laser processing machine 40, and as illustrated in FIG. 6, a dicing tape T2 is bonded to a back surface Fb of an annular frame F, which centrally has an opening of an inner diameter greater than a diameter of the wafer 10, such that the dicing tape T2 closes the opening, and the wafer 10 is then disposed in the opening with the back surface 10b of the wafer 10 directed downwards, to bond the back surface 10b of the wafer 10 to the dicing tape T2, whereby the wafer 10 is supported on the annular frame F via the dicing tape T2 (frame supporting step).

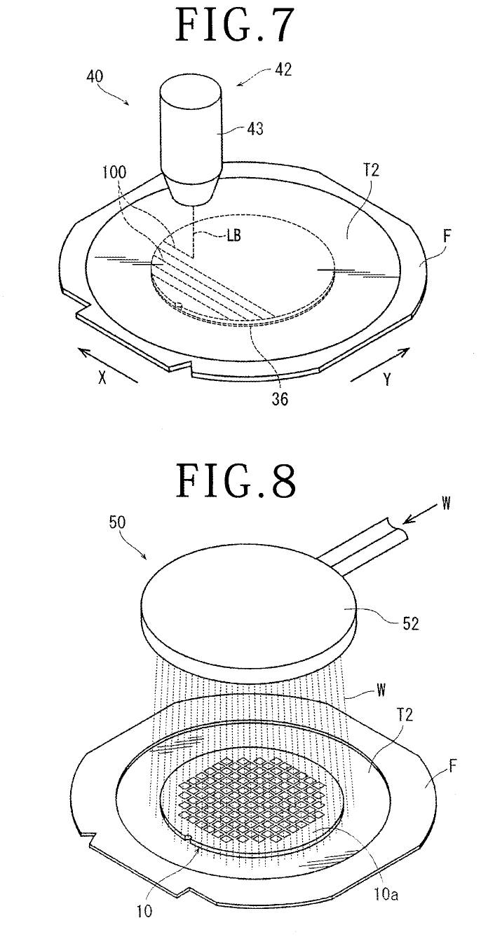

It is to be noted that the present invention is not limited to performing the frame supporting step after the modified-layer forming step, and the frame supporting step described based on FIG. 6 may be performed before the modified-layer forming step. If the above-described frame supporting step is performed before the modified-layer forming step, the wafer 10 supported on the annular frame F via the dicing tape T2 is transferred to a laser processing machine similar to the laser processing machine 40 illustrated in FIG. 5A, and as illustrated in FIG. 7, the annular frame F is placed and held by suction on the chuck table 41 (which is omitted from illustration in FIG. 7) with the wafer 10 directed downwards on the side of the front surface 10a and upwards on a side of the dicing tape T2. As also illustrated in FIG. 7, the above-described modified-layer forming step may then be performed from the side of the dicing tape T2 to form modified layers 100 along the dividing lines 14.

After the modified-layer forming step and the frame supporting step have been performed as described above, the wafer 10 is transferred to a resin removal device 50, only a part of which is illustrated in FIG. 8. In the resin removal device 50, a disk-shaped shower unit 52 is arranged as illustrated in FIG. 8, and to the shower unit 52, an unillustrated pure water supply unit is connected to supply pure water W. By activating the pure water supply unit, the pure water W is supplied in a spray pattern from a lower surface of the shower unit 52. The wafer 10 supported on the annular frame F is positioned below the shower unit 52 with the side of the front surface 10a directed upwards, and the pure water W is supplied from the shower unit 52 to remove the water-soluble resin 36 (resin removing step).

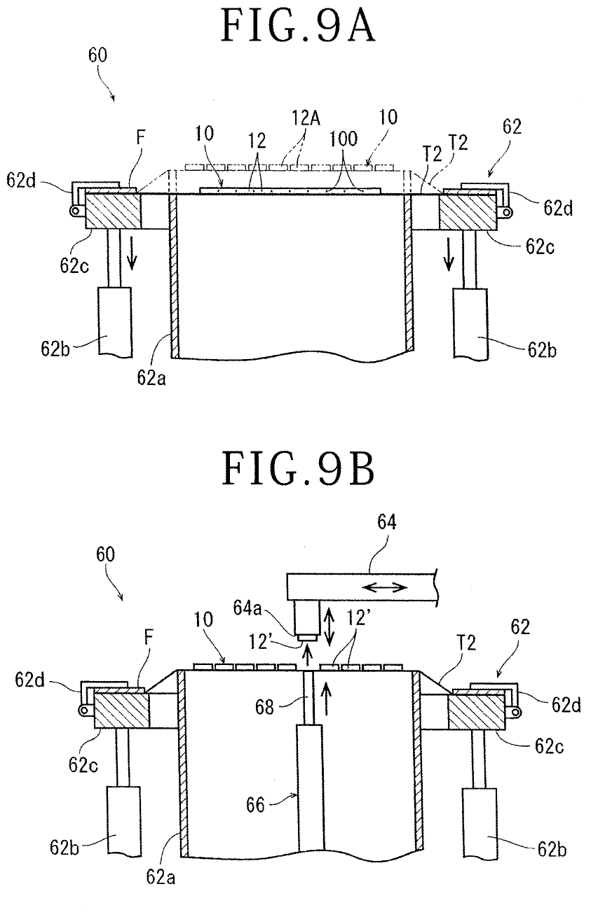

After the resin removing step has been performed as described above, the wafer 10 is transferred to a dividing machine 60 illustrated in FIG. 9A, to perform a dividing step in which an external force is applied to the wafer 10 to divide the wafer 10 into individual device chips. In the dividing machine 60, an external force applying unit 62 is arranged. As illustrated in FIG. 9A, the external force applying unit 62 includes a cylindrical expansion drum 62a, a plurality of air cylinders 62b that are disposed adjacent to the expansion drum 62a at intervals in a peripheral direction and that extend upwards, an annular holding member 62c connected to upper ends of the respective air cylinders 62b, and a plurality of clamps 62d arranged at intervals in the peripheral direction on an outer peripheral edge portion of the holding member 62c. The expansion drum 62a has an inner diameter greater than the diameter of the wafer 10 and an outer diameter smaller than an inner diameter of the annular frame F. On the other hand, the holding member 62c has a diameter dimension corresponding to that of the annular frame F, so that the annular frame F is configured to be placed on a flat upper surface of the holding member 62c.

As illustrated in FIG. 9A, the air cylinders 62b are configured to lift and lower the holding member 62c between a home position, at which the upper surface of the holding member 62c is at substantially the same height as an upper end of the expansion drum 62a, and an expanding position, at which the upper surface of the holding member 62c is located lower than the upper end of the expansion drum 62a. It is to be noted that, in FIG. 9A, the wafer 10 held on the dicing tape T2 is illustrated to be lifted and lowered as indicated by two-dot chain lines and solid lines, respectively, for the convenience of description, although the holding member 62c is lifted and lowered in practice.

When the dividing step is performed, the annular frame F is first placed on the upper surface of the holding member 62c positioned at the home position with the front surface 10a of the wafer 10 in which the modified layers 100 have been formed through the above-described modified-layer forming step, directed upwards. Then, the annular frame F is fixed by the clamps 62d, and the holding member 62c is lowered to the expanding position, whereby, as indicated by the two-dot chain lines in FIG. 9A, an external force is applied to the wafer 10 bonded to the dicing tape T2 such that the wafer 10 is radially expanded. As a consequence, the devices 12 formed on the wafer 10 are divided into individual device chips 12A with the modified layers 100 formed along the dividing lines 14 serving as division start points, and the dividing step is completed. It is to be noted that the dividing step in the present invention is not limited to the above-described application of an external force by the external force applying unit 62. The wafer 10 may also be divided into the individual device chips 12A, for example, by rolling an elastic roller under pressure on the front surface 10a of the wafer 10 to apply an external force to the wafer 10.

After the dividing step has been performed as described above, a pickup step is performed to pick up the device chips 12A from the dicing tape T2. In the above-described dividing machine 60, a pickup unit 64 is also arranged as illustrated in FIG. 9B. The pickup unit 64 is configured to be movable in a horizontal direction and in an up-to-down direction. Unillustrated suction means is connected to the pickup unit 64, so that the pickup unit 64 is configured to draw each of the individually divided device chips 12A to a lower surface of a distal end portion 64a thereof. Further, push-up means 66 is arranged inside the expansion drum 62a. The push-up means 66 is configured to move in the horizontal direction integrally with the distal end portion 64a of the pickup unit 64. When the distal end portion 64a of the pickup unit 64 is lowered to draw a desired one of the device chips 12A, a lift rod 68 of the push-up means 66 is raised to act such that the desired device chip 12A is pushed up upwards. Owing to the inclusion of such configurations, each device chip 12A is picked up from the dicing tape T2 and is transferred to and put into an unillustrated storage case, and the pickup step is completed.

In the above-described embodiment, the front surface 10a of the wafer 10 is covered with the water-soluble resin 36 when the modified-layer forming step is performed. Therefore, the devices 12 on the front surface 10a of the wafer 10 are protected by the water-soluble resin 36, and further, the heat that occurs by the irradiation of the laser beam LB is allowed to effectively dissipate, so that the problem that devices are deteriorated in electrical characteristics is solved. Moreover, even if leak light of the laser beam LB applied from the side of the back surface 10b of the wafer 10 reaches the side of the front surface 10a, the front surface 10a of the wafer 10 is covered with the water-soluble resin 36 without any self-adhesive layer, thereby solving the problem that the self-adhesive material in such a self-adhesive layer is modified by the leak light and the self-adhesive material thus modified sticks to the front surface 10a of the wafer 10 to deteriorate the quality of the device chips 12A.

The present invention is not limited to the above-described embodiment, and includes a variety of modifications. For example, in the above-described embodiment, after the protective tape separation step has been performed and the protective tape T1 has been separated, the water-soluble resin application step is performed to apply the water-soluble resin 36 to the front surface 10a of the wafer 10. Without being limited to this, the water-soluble resin application step may be performed on the front surface 10a of the wafer 10 in advance before the protective tape arrangement step, thereby making it also possible to cover the front surface 10a of the wafer 10 with the water-soluble resin 36 beforehand. If this is the case, the water-soluble resin 36 applied to the front surface 10a of the wafer 10 is exposed when the protective tape separation step is performed.

Further, the processing method of the present embodiment may also be modified such that the water-soluble resin application step is performed to apply the water-soluble resin 36 to the front surface 10a of the wafer 10, the modified-layer forming step is performed to form the modified layers 100 along the dividing lines 14 inside the wafer 10, the protective tape arrangement step is performed to arrange the protective tape T1 on the front surface 10a of the wafer 10, the grinding step is performed to grind the wafer 10 at the back surface 10b thereof, the frame supporting step is performed to support the wafer 10 on the annular frame F via the dicing tape T2, the protective tape separation step is performed to separate the protective tape T1 from the front surface 10a of the wafer 10, the resin removing step is performed to remove the water-soluble resin 36 from the front surface 10a of the wafer 10, and then the dividing step and the pickup step are performed. The advantageous effects of the present invention can therefore be exhibited at least insofar as, before the modified-layer forming step, the water-soluble resin application step is performed to apply the water-soluble resin 36 to the front surface 10a of the wafer 10.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing method of a wafer with a plurality of devices formed on a front surface thereof and defined by a plurality of intersecting dividing lines, the processing method comprising:
a protective tape arrangement step of arranging a protective tape on the front surface of the wafer;
a holding step of holding, on a chuck table, the wafer on a side of the protective tape;
a grinding step of grinding the wafer at a back surface thereof to thin the wafer;
a protective tape separation step of separating the protective tape from the front surface of the wafer;
a water-soluble resin application step of applying a water-soluble resin to the front surface of the wafer;
a modified-layer forming step of applying a laser beam of a wavelength that has transmissivity for the wafer, from the back surface of the wafer with a focal point of the laser beam positioned corresponding to each of the dividing lines inside the wafer, thereby forming modified layers along the each of the dividing lines;
a frame supporting step of bonding a dicing tape to a back surface of an annular frame that centrally has an opening of an inner diameter greater than a diameter of the wafer, such that the dicing tape closes the opening, and then disposing the wafer in the opening with the back surface of the wafer directed downwards, to bond the back surface of the wafer to the dicing tape, thereby supporting the wafer on the annular frame via the dicing tape;
a resin removing step of removing the wafer-soluble resin from the front surface of the wafer;
a dividing step of applying an external force to the wafer, thereby dividing the wafer into individual device chips; and
a pickup step of picking up the device chips from the dicing tape.

2. The processing method according to claim 1, wherein the water-soluble resin application step is performed before the protective tape arrangement step, and the water-soluble resin is exposed in the protective tape separation step.

3. The processing method according to claim 1, wherein the frame supporting step is performed before the modified-layer forming step, and the laser beam is applied from a side of the dicing tape in the modified-layer forming step.
